(19) United States
(12) Patent Application Publication
(10) Pub. No.: US 2017/0250676 A1
(43) Pub. Date: Aug. 31, 2017

(54) AUDIO PROCESSING WITH MODIFIED CONVOLUTION

(71) Applicant: Lachlan BARRATT, Summer Hill (AU)

(72) Inventor: Lachlan BARRATT, Summer Hill (AU)

(21) Appl. No.: 15/514,488

(22) PCT Filed: Sep. 26, 2015
(86) PCT No.: PCT/AU2015/050576

§ 371 Date: Mar. 24, 2017

Related U.S. Application Data
(60) Provisional application No. 62/056,343, filed on Sep. 26, 2014.
(60) Provisional application No. 62/091,312, filed on Dec. 12, 2014.
(60) Provisional application No. 62/165,849, filed on May 22, 2015.

(51) Int. Cl. H03H 17/06; H03H 17/02

(52) U.S. Cl. CPC H03H 17/0621; H03H 17/0248

(57) ABSTRACT

A method of processing a digital signal includes providing a digital filter including neighbouring sample points and performing a sample rate increase on the digital filter to provide intermediate sample points between adjacent neighbouring sample points, said intermediate points being populated dependent on a weighted influence determined in the time domain of a predetermined number of the neighbouring sample points. The digital filter is applied to the signal where: i) one of the neighbouring sample points of the filter is applied to a corresponding sample point of the signal; ii) offset and neighbouring sample points of the signal are defined either side of the corresponding sample point, said offset points being offset in the time domain relative to the respective neighbouring sample points of the filter; and iii) the neighbouring sample points of the filter are applied to respective of the offset and neighbouring sample points of the signal.

### TECHNICAL FIELD

1. The present invention relates broadly to a method of processing a digital signal such as an audio signal. The invention also relates broadly to a computer or device-readable medium for processing a digital signal or filter, and a computer system for processing a digital signal or filter. The invention extends to other digital processing including processing images and other signals including signals associated with digital communications.

### BACKGROUND OF INVENTION

2. In digital recording and playback an analog signal representative of audio is converted into a digital signal which lends itself to manipulation and storage. The conversion is performed in an analog to digital converter (ADC). The stored digital signal can be converted back to an analog signal in a digital to analog converter (DAC). The analog signal is played back using conventional audio equipment such as amplifiers and speakers. The digital signal can be manipulated prior to the DAC to improve its quality before playback. This manipulation includes audio EQ where selected parts of the frequency spectrum of the audio are filtered to, for example, compensate for irregularities in the frequency response. The audio may also be filtered to resolve problems from its conversion into a digital signal or back to an analog signal. This manipulation in the digital domain also includes audio emulation, compression, time-stretching and pitch-shifting.

### SUMMARY OF INVENTION

3. According to a first aspect of the present invention there is provided a method of processing a digital signal, said method comprising the steps of:

providing a digital filter including a plurality of neighbouring sample points;

performing a sample rate increase on the digital filter to provide a plurality of intermediate sample points between adjacent of the neighbouring sample points, said intermediate points being populated dependent on a weighted influence determined in the time domain of a predetermined number of the neighbouring sample points;

applying the digital filter to the signal where:
i) one of the neighbouring sample points of the filter is applied to a corresponding sample point of the signal;
ii) offset and neighbouring sample points of the signal are defined either side of the corresponding sample point of the signal, said offset points being offset in the time domain relative to the respective neighbouring sample points of the filter; and
iii) the neighbouring sample points of the filter are applied to respective of the offset and neighbouring sample points of the signal.

4. Preferably the method comprises an initial step of selecting an initial digital filter having a sample resolution substantially the same as the signal, and expanding the selected initial filter to effect offset of the offset sample points of the signal relative to the respective neighbouring sample points of the filter.

5. Preferably the step of applying the digital filter to the signal involves applying said filter at an adjusted sampling rate proportional to the offset of the sample points of the signal relative to the respective neighbouring sample points of the filter.

6. Preferably the filter is at least in part represented by an impulse response produced by an impulse fed to said filter and wherein the neighbouring sample points of the impulse response are offset in the time domain relative to the respective offset sample points of the signal. More preferably the impulse response is in the time domain represented at least in part by a mathematical function.

7. According to a second aspect of the invention there is provided a method of processing a digital signal, said method comprising the steps of:

providing another digital signal including a plurality of neighbouring sample points;

performing a sample rate increase on the other digital signal to provide a plurality of intermediate sample points between adjacent of the neighbouring sample points, said intermediate points being populated dependent on a weighted influence determined in the time domain of a predetermined number of the neighbouring sample points;

applying the other signal to the signal where:
(i) one of the neighbouring sample points of the other signal is applied to a corresponding sample point of the signal;
(ii) offset and neighbouring sample points of the signal are defined either side of the corresponding sample point of the signal, said offset points being offset in the time domain relative to the respective neighbouring sample points of the other signal; and
(iii) the other of the neighbouring sample points of the other signal are each applied to respective of the offset and neighbouring sample points of the signal.

8. Preferably the method comprises an initial step of expanding the other signal in its time domain to effect offset of the offset sample points relative to the respective neighbouring sample points of the signal.

9. Preferably the method comprises the step of representing the other signal in the time domain by at least its cosine and sine components. More preferably the cosine components are replaced at least in part with square-shaped wave components for valve-type emulation on application to the signal. Alternatively the sine components are replaced at least in part with triangular-shaped wave components for transistor-type emulation on application to the signal.

10. Preferably the other signal includes random noise. More preferably the random noise is represented by discrete values of a mathematical function to be applied to the signal. Even more preferably one or more of the discrete values of the random noise is replaced with either a zero (0) or one 1).

11. Preferably the step of applying the other signal to the signal involves applying said other signal at an adjusted sampling rate proportional to the offset of the offset sample points.

12. Preferably the method also comprises a step of deriving or constructing a modulation envelope to be applied as the other signal. More preferably the modulation envelope is derived from an initial envelope representing value changes in the other signal. Even more preferably the initial envelope is manipulated by a mathematical function to obtain the modulation envelope.

13. Preferably the signal and/or the other signal includes an audio signal.

14. According to a third aspect of the invention there is provided a method of processing a digital audio filter, said method comprising the steps of:

providing an audio signal including a plurality of neighbouring sample points;

performing a sample rate increase on the audio signal to provide a plurality of intermediate sample points between adjacent of the neighbouring sample points, said intermediate points being populated dependent on a weighted influence determined in the time domain of a predetermined number of the neighbouring sample points;

applying the audio signal to the digital filter where:
i) one of the neighbouring sample points of the signal is applied to a corresponding sample point of the filter;
ii) offset and neighbouring sample points of the filter are defined either side of the corresponding sample point of the filter, said offset points being offset in the time domain relative to the respective neighbouring sample points of the signal;
iii) the neighbouring sample points of the signal are applied to respective of the offset and neighbouring sample points of the filter.

15. Preferably the method comprises an initial step of including additional sample points in the audio signal between the neighbouring sample points to effect time-stretching of the audio signal prior to its application to the filter. Alternatively or additionally the method involves applying the signal to the filter at an adjusted sampling rate to effect pitch-shifting of another audio signal to be filtered by the digital filter.

16. According to a fourth aspect of the invention there is provided a computer or device-readable medium including instructions for processing a digital signal or filter, said instructions when executed by a processor cause said processor to:

provide a digital filter or signal including a plurality of neighbouring sample points;

perform a sample rate increase on the digital filter or signal to provide a plurality of intermediate sample points between adjacent of the neighbouring sample points, said intermediate points being populated dependent on a weighted influence determined in the time domain of a predetermined number of the neighbouring sample points;

apply the digital filter to the signal or vice versa where
i) one of the neighbouring sample points of the filter or signal is applied to a corresponding sample point of the signal or filter, respectively;
ii) offset and neighbouring sample points of the signal or filter are defined either side of the corresponding sample point of the signal or filter, said offset points being offset in the time domain relative to the respective neighbouring sample points of the filter or signal; and
iii) the neighbouring sample points of the filter or signal are applied to respective of the offset and neighbouring sample points of the signal or filter, respectively.

17. According to a fifth aspect of the invention there is provided a computer or device-readable medium including instructions for processing a digital signal or filter, said instructions when executed by a processor cause said processor to:

provide another digital signal or filter including a plurality of neighbouring samples either side of the mid-point sample;

perform a sample rate increase on the digital filter or signal to provide a plurality of intermediate sample points between adjacent of the neighbouring sample points, said intermediate points being populated dependent on a weighted influence determined in the time domain of a predetermined number of the neighbouring sample points;

apply the other signal to the signal, or the other filter to the filter where:
(i) one of the neighbouring sample points of the other signal or other filter is applied to a corresponding sample point of the signal or the filter, respectively;
(ii) offset and neighbouring sample points of the signal or filter are defined either side of the corresponding sample point of the signal or filter, said offset points being offset in the time domain relative to the respective neighbouring sample points of the other signal or other filter; and
(iii) the other of the neighbouring sample points of the other signal or other filter are each applied to respective of the offset and neighbouring sample points of the signal or filter, respectively.

18. According to a sixth aspect of the invention there is provided a computer system for processing a digital signal or filter, said computer system comprising:

a digital filter or signal including a plurality of neighbouring sample points;

a processor configured to:

perform a sample rate increase on the digital filter or signal to provide a plurality of intermediate sample points between adjacent of the neighbouring sample points, said intermediate points being populated dependent on a weighted influence determined in the time domain of a predetermined number of the neighbouring sample points;

apply the digital filter to the signal or vice versa where:
i) one of the neighbouring sample points of the filter or signal is applied to a corresponding sample point of the signal or filter, respectively;
ii) offset sample points of the signal or filter are defined either side of the corresponding sample point of the signal or filter, said offset points being offset in the time domain relative to the respective neighbouring sample points of the filter or signal; and
iii) the neighbouring sample points of the filter or signal are applied to respective of the offset and neighbouring sample points of the signal or filter, respectively.

19. Accordingly to a seventh aspect of the invention there is provided a computer system for processing a digital signal or filter, said computer system comprising:

another digital signal or filter including a mid-point sample and a plurality of neighbouring samples either side of the mid-point sample;

a processer configured to:

perform a sample rate increase on the digital filter or signal to provide a plurality of intermediate sample points between adjacent of the neighbouring sample points, said intermediate points being populated dependent on a weighted influence determined in the time domain of a predetermined number of the neighbouring sample points;

apply the other signal to the signal, or the other filter to the filter where:
(i) one of the neighbouring sample points of the other signal or other filter is applied to a corresponding sample point of the signal or the filter, respectively;
(ii) offset sample points of the signal or filter are defined either side of the corresponding sample point of the signal or filter, said offset points being offset in the time domain relative to the respective neighbouring sample points of the other signal or other filter; and
(iii) the other of the neighbouring sample points of the other signal or other filter are each applied to respective of the offset and neighbouring sample points of the signal or filter.

### BRIEF DESCRIPTION OF DRAWINGS

20. In order to achieve a better understanding of the nature of the present invention a preferred embodiment of a method of digitally processing a signal will now be described, by way of example only, with reference to the accompanying drawings in which:

FIG. 1 is a schematic of application of embodiments of the invention in digital audio recording and playback;

FIG. 2 is a schematic illustration of modified convolution of a digital filter with a digital signal according to an embodiment of the invention;

FIGS. 3A and 3B are illustrations of alternative waveforms or components thereof represented by mathematical functions representing digital filters;

FIGS. 4A to 4D are schematics of different techniques for increasing the sample rate of the digital filter or signal;

FIG. 5 is a schematic illustration of valve-type emulation in applying one signal to another signal according to another aspect of the invention;

FIG. 6 is a schematic illustration of transistor-type emulation in applying one signal to another signal according to a further aspect of the invention;

FIGS. 7A and 7B are schematic illustrations of signal compression and associated signal processing steps according to another application of the present invention.

### DETAILED DESCRIPTION

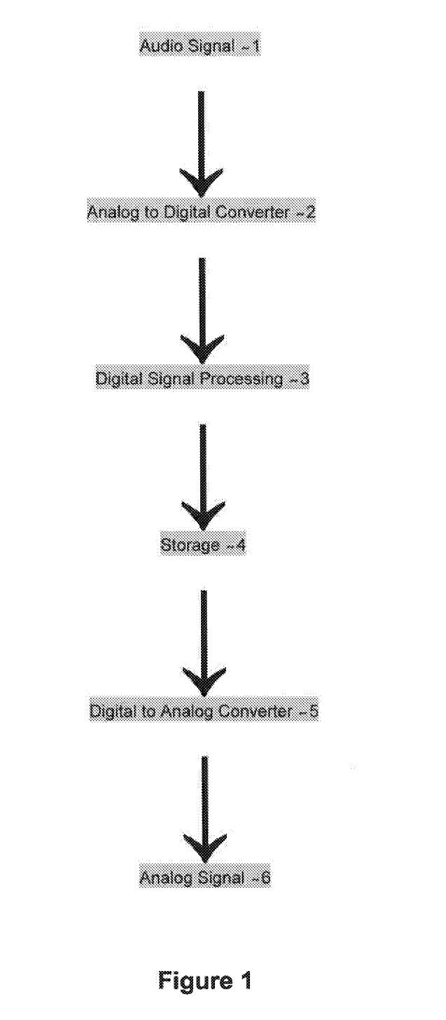

21. FIG. 1 shows application of the various embodiments of the invention in the course of digital audio recording and playback. The analog audio signal 1 is converted to a digital audio signal at an analog to digital converter (ADC) 2. The digital audio signal may then be subject to signal processing at digital processor 3 The processed digital signal is down-sampled and stored at storage memory 4 before a sample rate increase to increase its resolution prior to playback. The relatively high resolution digital audio signal is then converted back to an analog signal 6 at a digital to analog converter (DAC) 5. It will be understood that the various embodiments of the invention can be applied at the digital signal processor 3 where, for example:

(1). The digital signal is processed to provide either valve-type or transistor-type emulation in the signal;

(2). The digital signal undergoes various steps in signal processing to effect signal compression;

(3). The digital signal is processed for time-stretching or pitch-shifting;

(4). Filters are constructed for processing of the digital signal in order to influence its frequency response.

22. The invention in its preferred form is embodied in computer program code or software such as plugin software. The digital filter of the digital signal processor, or the digital signal, is represented by a particular frequency response. The particular frequency response is generally dependent on the impulse response of the filter or the signal which is characterised by the software or techniques of the various embodiment of this invention. The invention in its preferred embodiments is intended to cover the basic types of frequency response by which digital filters are classified including lowpass, highpass, bandpass and bandreject or notch filters. The digital filters are broadly categorised as Finite Impulse Response (FIR) or Infinite Impulse Response (IIR) filters.

23. In each of the applications described in the preceding paragraphs the method involves application of digital signals (or filters) to one another by adopting a modified convolution technique. In the case of filtering a digital signal, the general steps involved are as follows:

(1) Providing a digital filter including a mid-point sample and a plurality of neighbouring sample points either side of the mid-point sample;

(2) Performing a sample rate increase on the digital filter to provide a plurality of intermediate sample points between adjacent of the neighbouring sample points, said intermediate points being populated dependent on a weighted influence of a predetermined number of the neighbouring sample points;

(3) Applying the digital filter to the signal where:
i) the mid-point sample of the filter is applied to a corresponding sample point of the signal;
ii) offset and neighbouring sample points of the signal are defined either side of the corresponding sample point of the signal, said offset points being offset in the time domain relative to the respective neighbouring sample points of the filter; and
iii) the neighbouring sample points of the filter are each applied to respective of the offset and neighbouring sample points of the signal.

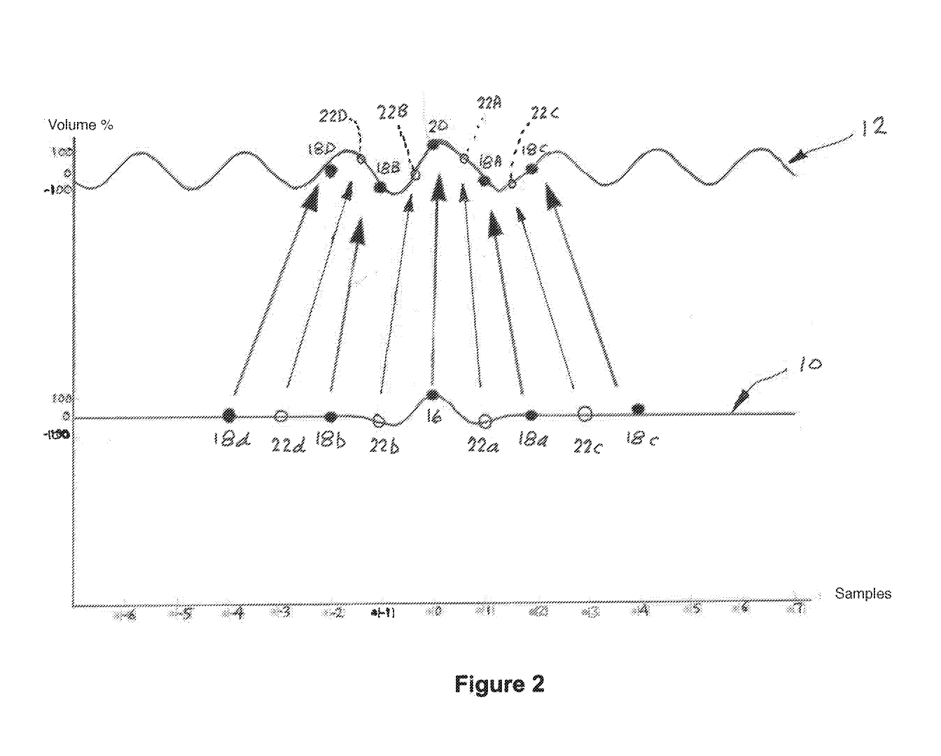

24. FIG. 2 illustrates this modified convolution technique where for simplicity the filter 10 is represented by a sinc function which is the sum of the cosine components in the time domain. In alternative embodiments the filter may be represented by other waveforms constructed from components represented by mathematical functions including:

(1) Sine functions for absolute time values represented in the time domain;

(2) Sine functions for time values represented in the time domain from zero (0) to positive infinitely only;

(3) Sinc functions for values represented in the time domain from zero (0) to positive infinity only;

(4) Absolute values of a cosine function in the time domain substantially limited to half a waveform cycle at its mid-point.

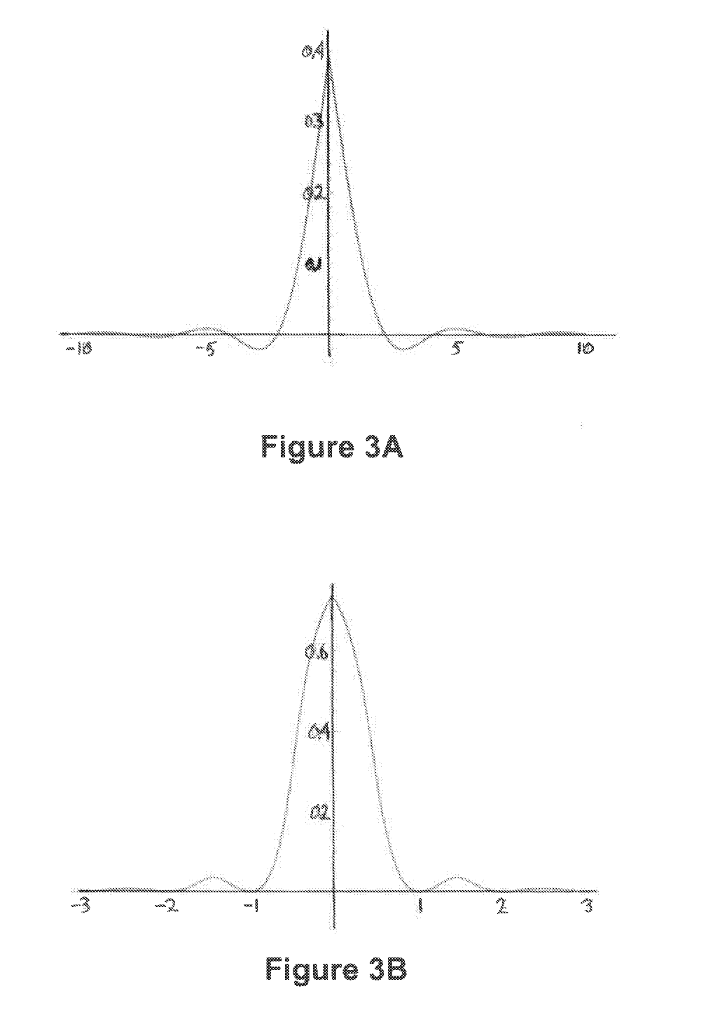

FIGS. 3A and 3B illustrate the component waveforms of items 1 and 4, respectively, summed across a relevant frequency range. The component waveforms of item 2 are effectively half the component waveforms of item 1. The component waveform of item 3 are similarly the waveforms of equation 1 but for positive time values only.

25. The applicant's co-pending International patent application PCT/AU2014/000317 describes in some detail waveforms constructed from components represented by sine functions for absolute time values. The disclosures of this PCT application are to be considered included herein by nature of this reference.

26. The waveform components may also be adjusted by for example applying a mathematical function to each of the components or the waveforms themselves. In one embodiment the waveforms or their components may be modified by applying an averaging curve having its width in the time domain adjusted proportional to the wavelength of the respective wave-forms. This modification of the waveform components is discussed in the applicant's co-pending International patent application No. PCT/AU2014/000321 the disclosures of which are to be considered included herein by nature of this reference.

27. FIG. 2 schematically illustrates one technique for applying the filter 10 to a signal 12 in modified convolution. The digital filter 10 represented by its corresponding filter waveform includes a mid-point sample 16 and a plurality of neighbouring sample points such as 18a to 18d located either side of the mid-point sample 16 (shown by solid dots). The signal 12 includes a corresponding sample point 20 which aligns in the time domain with the mid-point sample 16 of the digital filter 10. The digital signal 12 also includes neighbouring sample points 18A to 18D located either side of the corresponding sample point 20 (shown by solid dots). The corresponding sample points 18A to 18D are offset in the time domain relative to the respective neighbouring sample points 18a to 18d of the digital filter 10.

28. The filter 10 and the signal 12 have each undergone the same sample rate increase. For simplicity each of the filter 10 and signal 12 have been shown with a single intermediate sample point such as 22a and 22A (shown by hollow dots) respectively between adjacent of the neighbouring sample points, such as 16/18a and 18A/20. In practice it will be understood that depending on the sample rate increase or required resolution there will be many more intermediate sample points. The sample rate increase is performed by populating each of the intermediate sample points depending on a weighted influence determined in the time domain of a predetermined number of the neighbouring sample points. For example 1,024 neighbouring sample points may be taken into account with 512 sample points either side of the intermediate sample point being populated. The weighted influence may be calculated for each of the intermediate sample points by any one of the following exemplary techniques involving:

(1) Representative waveforms at respective of neighbouring sample points where values are combined at the intermediate sample points;

(2) A representative waveform at the intermediate sample point where values are combined at the neighbouring sample points;

(3) Representative waveforms at respective neighbouring sample points shifted midway to the intermediate sample point with values combined at the intermediate sample point;

(4) A representative waveform at the neighbouring sample points shifted midway to the intermediate sample point with values combined from the neighbouring sample points.

29. The filter of this embodiment may be constructed from cosine components represented by absolute values of a cosine function in the time domain substantially limited to half a waveform cycle at its mid-point. The half-cycle cosine components are summed across the relevant frequency range to obtain the relevant waveform, see for example FIG. 3B. In this case the half-cycle cosine waveform components are each weighted for substantially equal contribution to the filter. This weighting is approximated as equal areas under each of the half-cycle cosine component curves.

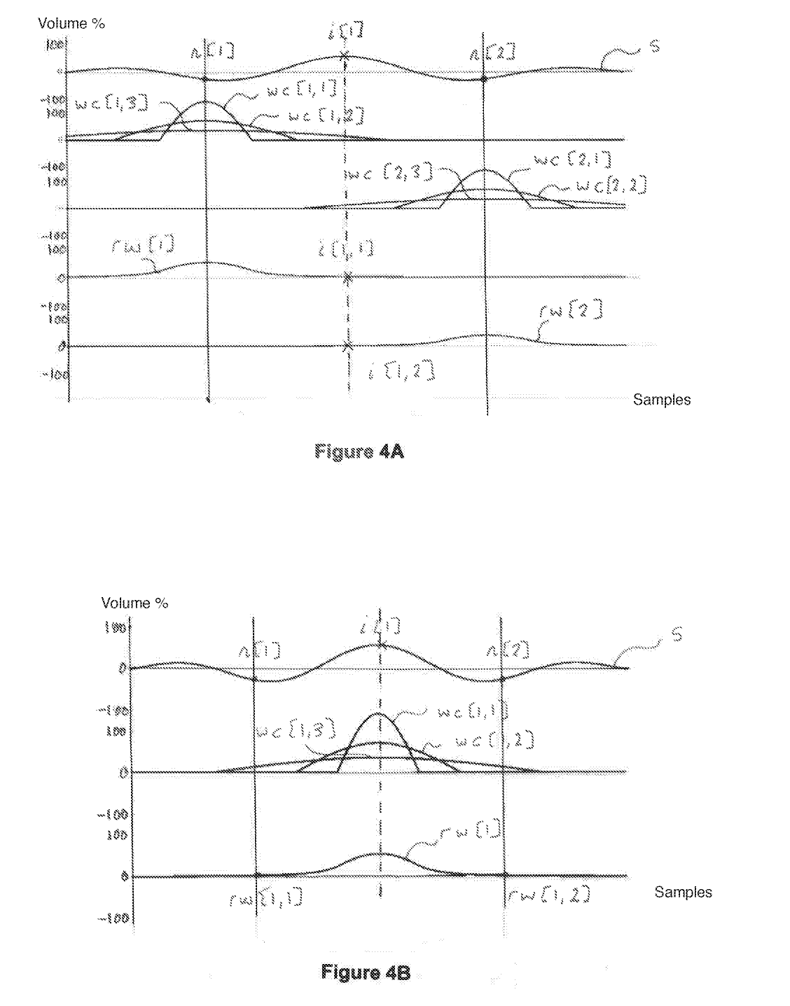

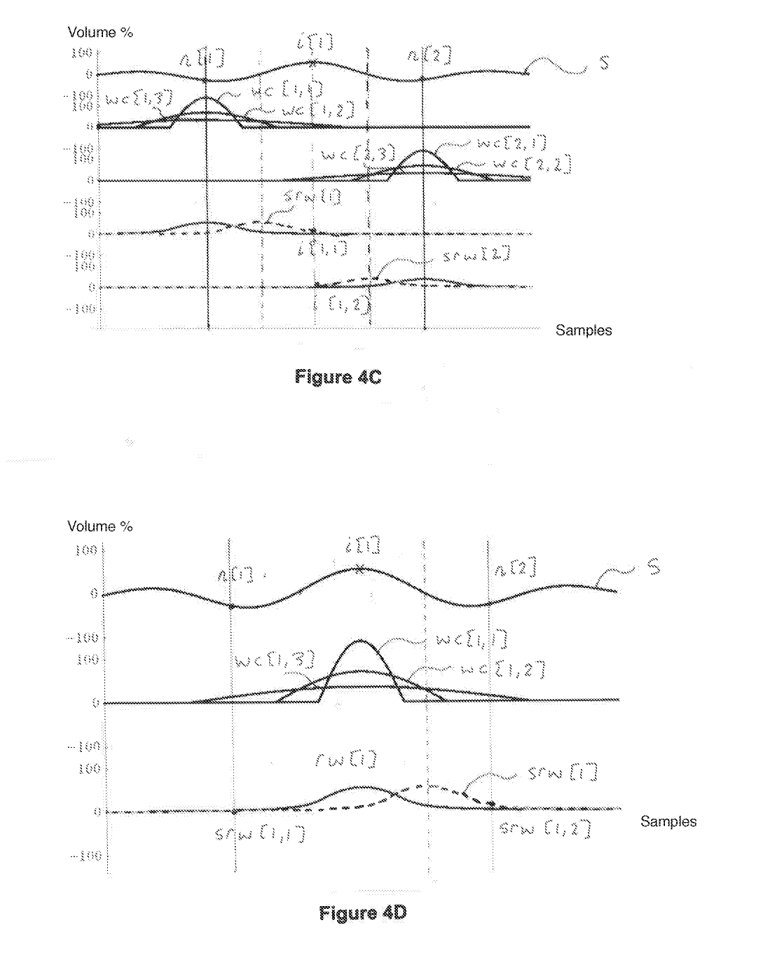

30. FIG. 4A schematically illustrates the technique utilising representative waveforms at neighbouring sample points with values combined at the intermediate sample point. In this embodiment the digital signal S or filter is represented at the predetermined number of the neighbouring sample points by its cosine components. For simplicity the signal S is shown at two neighbouring sample points n[1] and n[2] with a single intermediate sample point i[1]. In practice the resolution of the calculation may extend to many more neighbouring sample points, for example 1,024 sample points.

31. The digital signal S at n[1] is for simplicity represented with three weighted waveform components designated wc[1, 1] and wc[1, 2]. In practice the signal S will be represented by many more waveform components sufficient to cover the frequency content of the signal. Each of the waveform components are in this embodiment represented by absolute values of a cosine function in the time domain substantially limited to half a waveform cycle at its mid-point. The waveform components such as wc[1, 1], wc[1, 2] and wc[1, 3] are combined or in this exampled summed at the relevant neighbouring sample point n[1] to obtain a representative waveform designated rw[1]. With this technique the weighted influence is calculated by combining values for the representative waveforms such as rw[1] and rw[2] at the intermediate sample point by i[1]. The determined values at the intermediate sample point i[1] are in this example designated i[1, 1] and i[1, 2]. These steps are repeated for each of the intermediate sample points in order to populate the digital signal or filter at the increased sample rate.

32. FIG. 4B schematically illustrates the technique where the representative waveform is located at the intermediate sample point and values combined from the predetermined number of neighbouring sample points. For ease of reference the same nomenclature has been adopted in designating the various waveforms and sample points. In this embodiment the values to be combined from the neighbouring sample points such as n[1] and n[2] have been designated as rw[1, 1] and rw[1, 2] for the representative waveform rw[1].

33. FIG. 4C schematically illustrates representative waveforms at respectively neighbouring sample points but shifted midway toward the intermediate sample point under consideration. In this variation, values are combined for each of the shifted representative waveforms at the intermediate sample point. The shifted representative waveform for each of the neighbouring sample points n[1] and n[2] is shown in hidden line detail and designated as srw[1] and srw[2] respectively. The values are determined at the intermediate sample point i[1] for each of the waveforms srw[1] and srw[2] and these values designated as i[1, 1] and i[1, 2] respectively.

34. FIG. 4D schematically illustrates the technique where the representative waveform is shifted midway toward the intermediate sample point and the values combined from the neighbouring sample points. The shifted representative waveform is shown in hidden line detail and designated as srw[1]. The values to be combined for the shifted representative waveform srw[1] at the respective neighbouring sample points [1] and [2] are designated as srw[1, 1] and srw[1, 2].

35. In this embodiment the sample points of the digital signal 12 may be offset relative to the respective sample points of the filter 10 or vice versa by expansion of a filter waveform representative of an initial digital filter (not shown). The sample points of the initial digital filter or waveform align in the time domain with respective and corresponding sample points of the signal 12 and thus is of the same sample resolution. In this example the initial filter may be expanded in its time domain by a factor or multiplier of between two (2) and ten (10). The filter 10 has undergone its weighted sample rate increase to the increased or required resolution prior to its expansion. The expansion factor is in this example proportional to the sample rate increase.

36. In this embodiment the digital filter 10 is applied to the signal 12 at an adjusted sampling rate. This adjusted sampling rate compensates for and is substantially proportional to the offset of the sample points 18A to 18D of the signal 12 relative to the respective neighbouring sample points 18a to 18d of the filter 10. In this example the filter 10 is thus applied to the signal 12 at a fraction of the sample resolution of the initial filter.

37. In this example the application of the filter 10 to the signal 12 involves a modified form of convolution based on dot products of values at neighbouring and intermediate sample points of the filter and the signal, respectively. In considering a limited numbering of sample points this dot product methodology involves:

(1) Multiplying the mid-point sample 16 of the filter 10 with the corresponding sample point 20 of the signal 12;

(2) Multiplying each of the neighbouring sample points 18a to 18d of the filter 10 with their respective offset neighbouring sample points 18A to 18D of the signal 12 for a predetermined number of sample points;

(3) Multiplying each of the intermediate sample points 22a to 22d of the filter 10 with their respective offset intermediate sample points 22A to 22D of the signal 12;

(4) Summing the product results from the multiplications of steps 1 to 3;

(5) Shifting or stepping the digital filter 10 at its adjusted sampling rate wherein the mid-point sample 16 of the filter 10 aligns in the time domain with the offset sample point 18A of the signal 12;

(6) Repeating steps 1 to 4 with the filter 10 at this position;

(7) Continuing this modified convolution at the adjusted sampling rate stepping across a predetermined number of sample points in the signal 12.

38. In another aspect of the invention a digital signal is processed by imposing the frequency response of another digital signal. This is effected by applying the other signal to the signal adopting the modified convolution techniques described in the preceding paragraphs. In this instance the filter of the preceding aspect is replaced with the other signal. In other respects the processing of the digital signal is essentially the same as the previous aspect and has application in audio (such as valve and transistor type) emulation, and signal compression.

39. The other signal may be in the form of a modulation envelope constructed from any one or more of the following:

(1) Proportional representation of changes, such as volume changes, in the signal, see for example the applicant's copending U.S. provisional patent application No. 62/159,027;

(2) Mathematical functions depending on the required processing of the signal;

(3) Trigonometric functions or waveforms representative of the signal, such as half a waveform cycle of absolute values of cosine functions;

(4) Clipping the signal below a threshold value to directly derive the required modulation envelope in the form of a noise gate.

40. The other signal (or modulator) and signal may be reversed where the signal is applied to the modulator by the modified convolution technique. The modulator may be otherwise mathematically manipulated to obtain the required envelope.

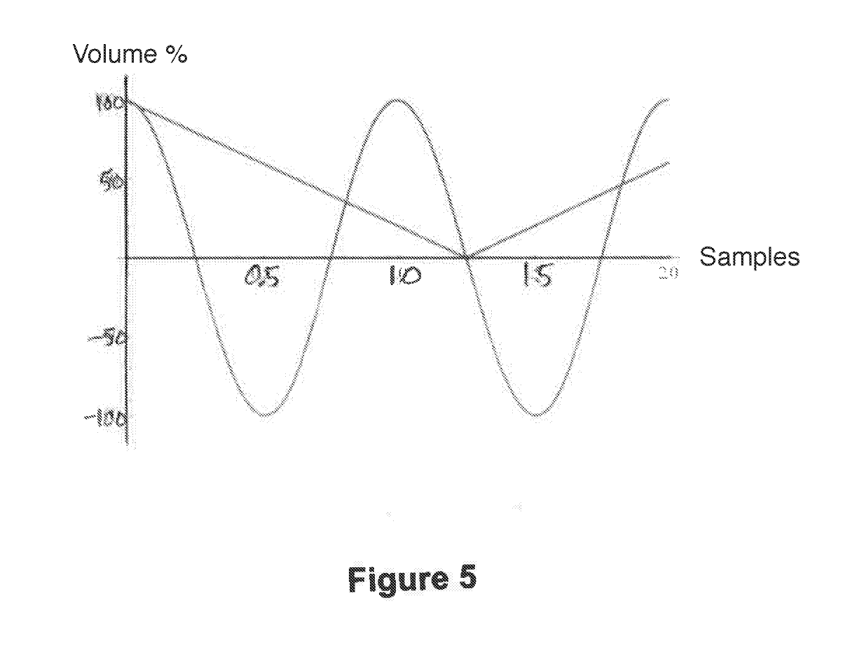

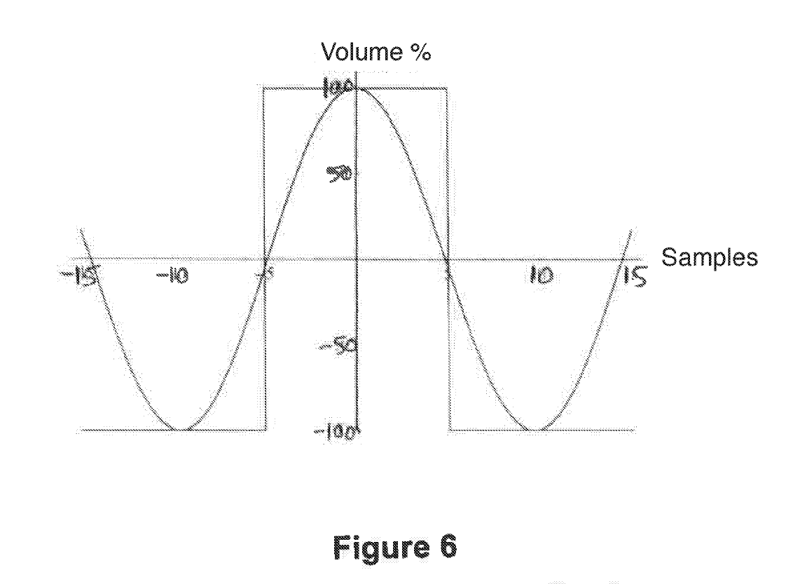

41. FIGS. 5 and 6 schematically illustrate application of this modified convolution in valve-type emulation and transistor-type emulation, respectively. The application of the other signal to the signal is the same in each of these applications and it is the representation of the other signal which varies in order to provide the required audio emulation. In both cases the other signal is at least partly represented in the time domain by at least its cosine and/or sine components. In the case of valve-type emulation the cosine and/or sine components of the other signal are replaced at least in part with square-shaped wave components. In the case of transistor-type emulation the cosine and/or sine components of the other signal are replaced at least in part with triangular-shaped wave components. These alternative techniques in processing the other signal prior to imposing its frequency response on the signal in modified convolution are illustrated for the cosine components in FIGS. 5 and 6 respectively. In practice the transistor-type emulation is typical of a lead guitar whereas the valve type emulation or distortion is typical of a backing guitar. The period or frequency of the square or triangular shaped waveforms may be varied to provide lower or higher harmonics when applied to the signal.

42. In an alternative embodiment the signal may be applied to the other signal which has its cosine and/or sine components replaced with square or triangular-shaped waveforms. In this example the frequency response of the signal is imposed on the other signal with both signals being in phase. In each of these alternative embodiments the cosine and/or sine component of the other signal may be at least in part replaced with a band of square-wave components which are summed across the relevant frequency range.

43. In another application random noise may be imposed on an audio signal by applying the modified convolution technique of the previous embodiments. In this case the random noise is applied as the other signal and is represented by discrete values, for example a mathematical function. The random noise signal may be adjusted by replacing discrete values with for example either a zero (0) or one (1). The addition of random zeros is understood to introduce odd or lower harmonics into the signal whereas the addition of random ones promotes even or upper harmonics. The random noise may be applied to the audio signal using the earlier-described convolution technique at an adjusted sampling rate which is a fraction, say substantially one eighth (⅛), the sample resolution. The other signal can thus be processed so that when applied to the signal it modulates or influences the audio signal. This process may be reversed where the signal is applied to the random noise using modified convolution.

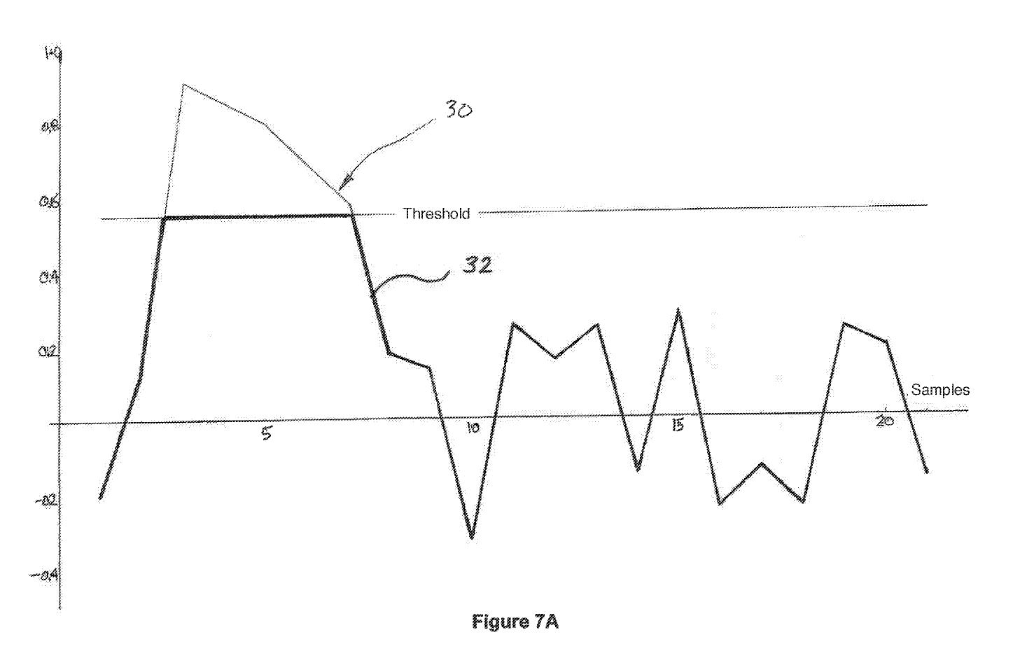

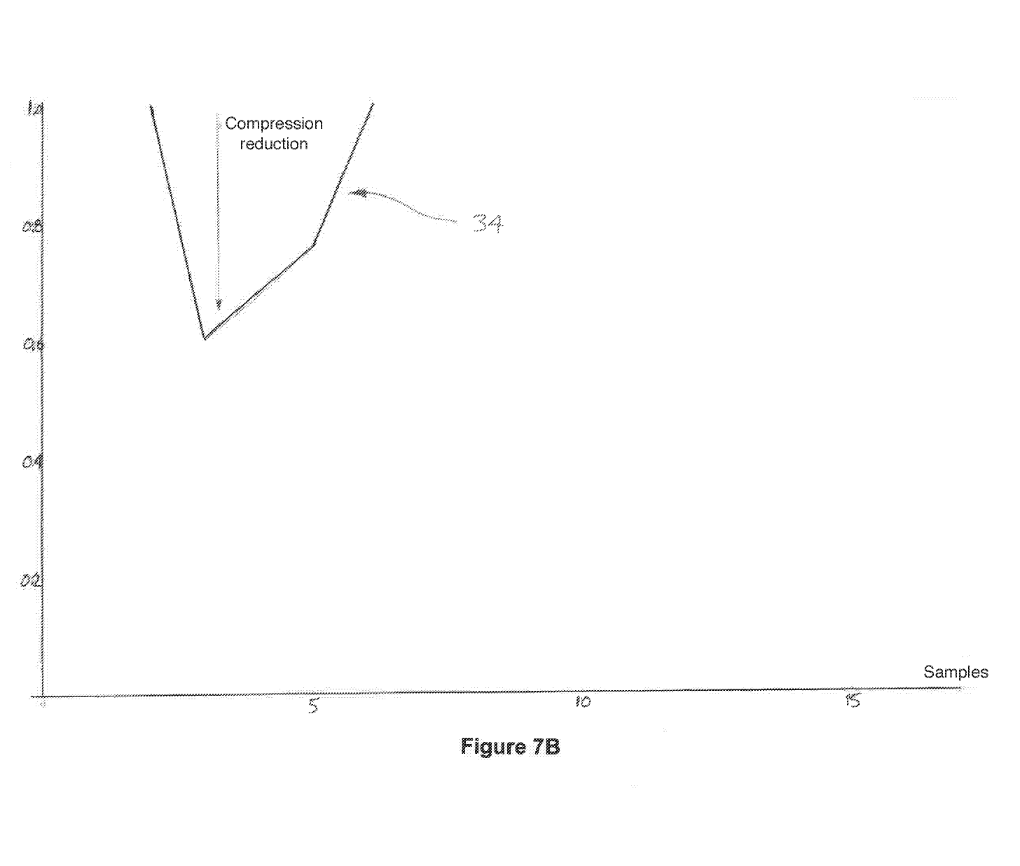

44. FIGS. 7A and 7B schematically illustrate one technique for signal compression in the context of the preceding embodiments of modified convolution. The other signal in this embodiment undergoes the following processing steps:

(1) The absolute values of the other signal are limited to a threshold value to obtain a limited waveform;

(2) The limited waveform is divided by the other signal to provide another signal or modulation envelope which is to be applied in modified convolution to the signal to effect its compression.

45. In its simplest form the other signal 30 is clipped to the threshold value to provide a clipped waveform 32 (shown bolded). The clipped waveform 32 is divided by the other signal 30 to provide another signal 34 which is to be convolved with the signal for compression. The other signal 34 may alternatively be limited by applying a mathematical function to obtain a desired variant of the limited waveform.

In another embodiment the signal may for a particular frequency range be represented in its cosine and sine components. These cosine and sine components for that frequency range or band are then combined to provide a virtual or mathematical filter for limiting. The filter may be limited to the required modulation envelope by applying a transfer function. The virtual filter may be applied in modified convolution directly to the equivalent cosine and sine components of the signal, or another filter which represents these cosine and sine components in accordance with another aspect of the invention.

46. In another aspect the invention involves modified convolution in the application of an audio signal to a digital filter. This aspect has application in time-stretching or pitch-shifting where:

(1) One or more sample points are inserted in the audio signal between neighbouring sample points to provide time-stretching;

(2) The time-stretched signal may be applied to the filter at an adjusted sampling rate;

(3) The adjusted sampling rate is varied to effect pitch-shifting of another audio signal to be filtered by the resulting digital filter.

The signal may be pitch-shifted without necessarily including additional sample points to time-stretch it. In this variation the signal is applied to the filter at a sampling rate different to its sample resolution to provide the required pitch-shifting.

47. The applicant's co-pending International patent application No. PCT/AU2014/000319 described several techniques for sample rate increases. The disclosures of this PCT application are to be considered included therein by nature of this reference.

48. The signal or filter may be processed before and/or after modified convolution as earlier-described. This processing includes but is not limited to the application of:

(1) One or more filters constructed from cosine and/or sine components having the application of proportional averaging curves in the time domain, see for example the applicant's International patent application no. PCT/AU2014/000321;

(2) Sample rate increases to the signal and/or filter using for example techniques disclosed in the applicant's International patent application no.'s PCT/AU2014/000318 and PCT/AU2014/000319 together with US provisional patent application No. 62/056,349;

(3) Sample zoning and the combination of sample values depending on the frequency of the zone as disclosed in the applicant's International patent application no. PCT/AU2015/000197;

(4) Modulation envelopes such as volume envelopes or frequency envelopes where for example a high pass filter is applied to the signal prior to convolution;

(5) Nyquist or other filters, for example the application of a Nyquist filter to noise prior to its application to a signal in modified convolution.

49. It is to be understood that the methods and techniques described can be implemented as computer-readable instructions stored on a computer-readable medium. The computer-readable instructions can be executed by a processor of practically any computer system including desktop, portable, tablet, hand-held, and/or any other computer device.

50. It is also to be understood that the present invention extends to computer-readable media for carrying or having computer-executable instructions stored thereon. The computer-readable media include RAM, ROM, EEPORM, CD-ROM or other optical disc storage, magnetic disc storages, or any other medium which carries or stores program code means in the form of computer-executable instructions. In the event of information being transferred or provided over a network or another communications connection to a computer, the computer is to be understood as viewing the connection (hardwired, wireless, or a combination thereof) as a computer-readable medium.

51. The contents of the applicant's following co-pending patent applications are to be taken as incorporated herein by these references:

(1) PCT/AU2014/000325 titled “Audio Filtering with Virtual Sample Rate Increases”;

(2) PCT/AU2014/000318 titled “Audio Sample Rate Increases”;

(3) PCT/AU2015/000197 titled “Modified Digital Filtering with Sample Zoning”.

52. Now that several preferred embodiments of the invention have been described it will be apparent to those skilled in the art that the method of processing the digital signal has at least the following advantages:

(1) The various techniques adopted in modified convolution lend themselves to a range of audio processing applications;

(2) The modified convolution techniques are adopted in the time domain with mathematical functions representing the signal or filter or components thereof;

(3) The modified techniques for convolution also lend themselves to processing of signals designed to obtain subsequent audio effects when applied to audio signals.

53. Those skilled in the art will appreciate that the invention described herein is susceptible to variations and modifications other than those specifically described. The processing of audio signals need not be limited to acoustics but extends to other sound applications including ultrasound and sonar. The invention also extends beyond audio signals to other signals including signals derived from a physical displacement such as that obtained from measurement devices, for example a strain gauge or other transducer which generally converts displacement into an electronic signal. The invention also covers digital processing of signals associated with digital communications. The invention in another embodiment is applied to imaging.

54. The filter(s) may be constructed or represented by fast fourier transform (FFT) algorithms rather than the trigonometric functions described in the preferred embodiments, such as the cosine and/or sine components. It is also possible that convolution can be applied in the frequency domain instead of the time domain. For example filtering in the frequency domain can involve application of FFT algorithms.

55. All such variations and modifications are to be considered within the scope of the present invention the nature of which is to be determined from the foregoing description.

1. A method of processing a digital signal or filter, said method comprising the steps of: providing a digital filter or signal including a plurality of neighbouring sample points;
performing a sample rate increase on the digital filter or signal to provide a plurality of intermediate sample points between adjacent of the neighbouring sample points, said intermediate points being populated dependent on a weighted influence determined in the time domain of a predetermined number of the neighbouring sample points;
applying the digital filter to the signal or vice versa where:
i) one of the neighbouring sample points of the filter or signal is applied to a corresponding sample point of the signal or filter, respectively;
ii) offset and neighbouring sample points of the signal or filter are defined either side of the corresponding sample point of the signal or filter, said offset points being offset in the time domain relative to the respective neighbouring sample points of the filter or signal; and
iii) the neighbouring sample points of the filter or signal are applied to respective of the offset and neighbouring sample points of the signal or filter, respectively.

2. A method as defined in claim 1 also comprising an initial step of selecting an initial digital filter having a sample resolution substantially the same as the signal, and expanding the selected initial filter to effect offset of the offset sample points of the signal relative to the respective neighbouring sample points of the filter.

3. A method as defined in claim 1 wherein the step of applying the digital filter to the signal involves applying said filter at an adjusted sampling rate proportional to the offset of the sample points of the signal relative to the respective neighbouring sample points of the filter.

4. A method as defined in claim 1 wherein the filter is at least in part represented by an impulse response produced by an impulse fed to said filter and wherein the neighbouring sample points of the impulse response are offset in the time domain relative to the respective sample points of the signal.

5. (canceled)

6. A method of processing a digital signal, said method comprising the steps of: providing another digital signal including a plurality of neighbouring sample points;
performing a sample rate increase on the other digital signal to provide a plurality of intermediate sample points between adjacent of the neighbouring sample points, said intermediate points being populated dependent on a weighted influence determined in the time domain of a predetermined number of the neighbouring sample points;
applying the other signal to the signal where:
i) one of the neighbouring sample points of the other signal is applied to a corresponding sample point of the signal;
ii) offset and neighbouring sample points of the signal are defined either side of the corresponding sample point of the signal, said offset points being offset in the time domain relative to the respective neighbouring sample points of the other signal; and
iii) the other of the neighbouring sample points of the other signal are each applied to respective of the offset and neighbouring sample points of the signal.

7. A method as defined in claim 6 also comprising an initial step of expanding the other signal in its time domain to effect offset of the offset sample points relative to the respective neighbouring sample points of the signal.

8. A method as defined in claim 6 further comprising the step of representing the other signal in the time domain by at least its cosine and sine components.

9. A method as defined in claim 8 wherein the cosine and/or sine components are replaced at least in part with square-shaped wave components for valve-type emulation on application to the signal.

10. A method as defined in claim 8 wherein the cosine and/or sine components are replaced at least in part with triangular-shaped wave components for transistor-type emulation on application to the signal.

11. (canceled)

12. A method as defined in claim 6 wherein the other signal includes random noise represented by discrete values of a mathematical function to be applied to the signal.

13. A method as defined in claim 12 wherein one or more of the discrete values of the random noise is replaced with either a zero (0) or one (1).

14. A method as defined in claim 6 wherein the step of applying the other signal to the signal involves applying said other signal at an adjusted sampling rate proportional to the offset of the offset sample points.

15. A method as defined in claim 6 also comprising a step of deriving or constructing a modulation envelope to be applied to the signal as the other signal.

16. (canceled)

17. (canceled)

18. (canceled)

19. (canceled)

20. A method as defined in claim 1 also comprising an initial step of including additional sample points in the audio signal between the neighbouring sample points to effect time-stretching of the audio signal prior to its application to the filter.

21. A method as defined in claim 19 wherein the method involves applying the signal to the filter at an adjusted sampling rate to effect pitch-shifting of another audio signal to be filtered by the digital filter.

22. A method as defined in claim 1 wherein the step of performing a sample rate increase involves calculating the weighted influence for each of the intermediate sample points by:
(i) representing the signal or the filter at the predetermined number of the neighbouring sample points at least in part by its cosine components, each component represented by absolute values of a cosine function in the time domain substantially limited to half a waveform cycle at its mid-point;
(ii) combining the half-cycle cosine components at each of the neighbouring sample points to obtain representative waveforms located at respective of the neighbouring sample points;
(iii) determining values for each of the representative waveforms at the intermediate sample point;
(iv) combining the determined values at the intermediate sample point to derive the weighted influence.

23. A method as defined in claim 1 wherein the step of performing a sample rate increase involves calculating the weighted influence for each of the intermediate sample points by:
representing the signal or the filter at one of the predetermined number of the neighbouring sample points at least in part by its cosine components, each component represented by absolute values of a cosine function in the time domain substantially limited to half a waveform cycle at its mid-point;
(ii) combining the half-cycle cosine components to obtain a representative waveform at the neighbouring sample point;
(iii) shifting the representative waveform in its time domain to align with the intermediate sample point;
(iv) determining values for the shifted representative waveform at each of the predetermined number of the neighbouring sample points;
(v) combining the determined values at the neighbouring sample points to derive the weighted influence.

24. A method as defined in claim 1 wherein the step of performing a sample rate increase involves calculating the weighted influence for each of the intermediate sample points by:
(i) representing the signal or the filter at the predetermined number of the neighbouring sample points at least in part by its cosine components, each component represented by absolute values of a cosine function in the time domain substantially limited to half a waveform cycle at its mid-point;
(ii) combining the half-cycle cosine components at each of the neighbouring sample points to obtain representative waveforms located at respective of the neighbouring sample points;
(iii) shifting each of the representative waveforms in their time domain substantially midway between the respective neighbouring sample points and the intermediate sample point;
(iv) determining values for each of the shifted representative waveforms at the intermediate sample point;
(v) combining the determined values at the intermediate point to derive the weighted influence.

25. A method as defined in claim 1 wherein the step of performing a sample rate increase involves calculating the weighted influence for each of the intermediate sample points by:
(i) representing the signal or the filter at one of the predetermined number of the neighbouring sample points at least in part by its cosine components, each component represented by absolute values of a cosine function in the time domain substantially limited to half a waveform cycle at its mid-point;
(ii) combining the half-cycle cosine components to obtain a representative waveform at the neighbouring sample point;
(iii) shifting the representative waveform in its time domain substantially midway between the neighbouring sample point and the intermediate sample point;
(iv) determining values for the shifted representative waveform at each of the predetermined number of the neighbouring sample points;
(v) combining the determined values at the neighbouring sample points to derive the weighted influence.

26. (canceled)

27. A non-transitory computer or device-readable medium including instructions for processing a digital signal or filter, said instructions when executed by a processor cause said processor to:
provide a digital filter or signal including a plurality of neighbouring sample points;
perform a sample rate increase on the digital filter or signal to provide a plurality of intermediate sample points between adjacent of the neighbouring sample points, said intermediate points being populated dependent on a weighted influence determined in the time domain of a predetermined number of the neighbouring sample points;
apply the digital filter to the signal or vice versa where
i) one of the neighbouring sample points of the filter or signal is applied to a corresponding sample point of the signal or filter, respectively;
ii) offset and neighbouring sample points of the signal or filter are defined either side of the corresponding sample point of the signal or filter, said offset points being offset in the time domain relative to the respective neighbouring sample points of the filter or signal; and
iii) the neighbouring sample points of the filter or signal are applied to respective of the offset and neighbouring sample points of the signal or filter, respectively.

28. (canceled)

29. (canceled)

30. (canceled)
